(19) United States
(12) Patent Application Publication
(10) Pub. No.: US 2016/0124050 A1
(43) Pub. Date: May 5, 2016

(54) STORAGE BATTERY TYPE VEHICLE, CHARGE MANAGEMENT SYSTEM, AND CHARGE MANAGEMENT METHOD

(71) Applicant: KOMATSU LTD., Tokyo (JP)

(72) Inventor: Feng HUA, Hiratsuka-shi (JP)

(73) Assignee: KOMATSU LTD., Tokyo (JP)

(21) Appl. No.: 14/238,553

(22) PCT Filed: Sep. 20, 2013
(86) PCT No.: PCT/JP2013/075491

§ 371 Date: Feb. 12, 2014

(51) Int. Cl. G01R 31/36; H02J 7/00; B60L 11/18

(52) U.S. Cl. CPC G01R 31/3606; B60L 11/1816; B60L 11/1838; H02J 7/0047; H02J 7/0029

(57) ABSTRACT

A storage battery type vehicle configured to charge a storage battery mounted on a vehicle via a charging cable connecting the vehicle to a stationary battery charger fixed outside the vehicle, the storage battery type vehicle including: a state information acquisition unit configured to acquire state information of the stationary battery charger via the charging cable; and a communication unit configured to transmit the state information to outside.

### FIELD

The present invention relates to a storage battery type vehicle, a charge management system, and a charge management method that allows for prompt recognition as to whether or not a stationary battery charger is abnormal even when there is no management communication facility such as communication equipment provided to the stationary battery charger outside the vehicle.

### BACKGROUND

Forklifts are roughly categorized into the engine type forklift and the battery type (storage battery type) forklift in view of their motive power source. With respect to the battery type forklift, the forklift is parked at the charging place and battery is charged in nighttime that is out of operation time, for example.

Further, there are two types of the battery type forklift, one of which has a battery charger mounted within the vehicle body and employs a system for charging the battery via that battery charger, while the other has no battery charger mounted within the vehicle body and employs a system for charging the battery using a battery charger fixed outside the vehicle (a stationary battery charger). The battery type forklift using the stationary battery charger does not need to have the battery charger mounted within the vehicle body, so that vehicle body can be compact and the manufacturing cost can be suppressed.

It is noted that Patent Literature 1 relates to a storage battery type vehicle that has a battery charger mounted within the vehicle body and charges the battery mounted on the vehicle via the charging cable that connects the vehicle to the power supply outside the vehicle, and it discloses that, when an abnormality occurs in the char cine process, the abnormal state is notified to the outside by email via the communication equipment mounted on the vehicle body.

### CITATION LIST

### Patent Literature

Patent Literature 1: Japanese Laid-open Patent Publication No. 2011-72081

### SUMMARY

### Technical Problem

By the way, when the storage battery type vehicle including the battery type forklift uses the stationary battery charger fixed outside the vehicle and, in the case where there is a failure in the stationary battery charger, other storage battery type vehicle and/or the manager who manages the remote stationary battery charger cannot promptly recognize this failure. For example, in the case where an abnormality occurs in the stationary battery charger fixed outside the vehicle during the charging of the battery type forklift using the stationary battery charger at nighttime and the charging was not properly made, the operator of the battery type forklift is likely to notice the abnormality of the stationary battery charger at the time of starting work in the next morning and contact with the manager of the stationary battery charger. As a result, the manager of the stationary battery charger will recognize with delay the abnormality occurring at the stationary battery charger. Further, in this case, the operator of the battery type forklift can know only the fact that the charging was not properly made but cannot know whether or not the stationary battery charger is abnormal. As a result, the fact that the stationary battery charger is abnormal cannot be known before a person who is in charge of maintenance and inspection of the stationary battery charger comes to the place where the stationary battery charger is installed.

The present invention has been made taking the above into consideration and aims to provide a storage battery type vehicle, a charge management system, and a charging management method that allows for prompt recognition as to whether or not the stationary battery charger is abnormal even when there is no management communication facility such as communication equipment provided to the stationary battery charger outside the vehicle.

### Solution to Problem

To overcome the problems and achieve the object, according to the present invention, according to the present invention, a storage battery type vehicle configured to charge a storage battery mounted on a vehicle via a charging cable connecting the vehicle to a stationary battery charger fixed outside the vehicle, the storage battery type vehicle comprises: a state information acquisition unit configured to acquire state information of the stationary battery charger via the charging cable; and a communication unit configured to transmit the state information to outside.

In the present invention, the storage battery type vehicle further comprises an abnormality determination unit configured to determine whether or not the state information acquired by the state information acquisition unit is abnormality information indicating an abnormality of the stationary battery charger, wherein the communication unit transmits the state information to the outside when the state information is the abnormality information.

In the present invention, when the state information acquired by the state information acquisition unit is abnormality information indicating an abnormality of the stationary battery charger or normality information indicating a normality of the stationary battery charger, the communication unit transmits either one of the abnormality information and the normality information to the outside.

In the present invention, the storage battery type vehicle according to further comprises an information addition unit configured to add additional information to the state information.

In the present invention, the additional information is position information of the vehicle.

In the present invention, the additional information is time information, of time of occurrence of abnormality of the stationary battery charger.

In the present invention, the state information includes identification information of the stationary battery charger.

In the present invention, the additional information is operating time and/or charging time of the vehicle.

According to the present invention, a storage battery type vehicle configured to charge a storage battery mounted on a vehicle via a charging cable connecting the vehicle to a stationary battery charger fixed outside the vehicle, wherein the storage battery type vehicle is a battery type forklift, the storage battery type vehicle comprising: a state information acquisition unit configured to acquire state information of the stationary battery charger via the charging cable; an abnormality determination unit configured to determine whether or not the state information acquired by the state information acquisition unit is abnormality information indicating an abnormality of the stationary battery charger; an information addition unit configured to add additional information to the state information; and a communication unit configured to transmit the state information to outside.

According to the present invention, a charge management system comprises: one or more stationary battery chargers fixed outside a vehicle; one or more storage battery type vehicles configured to charge a storage battery mounted on a vehicle via a charging cable connecting the vehicle to the one or more stationary battery chargers and be driven using charged power; and a management server configured to manage the one or more stationary battery chargers and the one or more storage battery type vehicles, wherein the one or more storage battery type vehicles and the management server are connected via a network, and wherein the one or more storage battery type vehicles comprises: a state information acquisition unit configured to acquire state information of the stationary battery charger via the charging cable; and a communication unit configured to transmit the state information to the management server, wherein the management server receives the state information to manage whether or not there is an abnormality occurring in the one or more stationary battery chargers.

In the present invention, the one or more storage battery type vehicles comprises an output unit configured to output the state information, wherein the management server comprises a management communication unit, wherein the management communication unit of the management server notifies the state information to the one or more storage battery type vehicles that are other than the storage battery type vehicle that has transmitted the state information and are connected to the network, and wherein the storage battery type vehicle that has received the state information from the management server outputs the received information to the output unit.

In the present invention, the state information is abnormality information of the stationary battery charger and is information to which one of more pieces of information of position information of the storage battery type vehicle that has acquired the state information, time information of time of occurrence of abnormality of the stationary battery charger, operating time of the storage battery type vehicle, charging time of the storage battery type vehicle, and identification information of the stationary battery charger are added.

In the present invention, upon receiving state information indicating restoration of the stationary battery charger, the management server notifies the one or more storage batter type vehicles of the state information indicating the restoration, and wherein the storage battery type vehicle that has received the state information indicating the restoration from the management server outputs the received state information indicating the restoration to the output unit.

According to the present invention, a charging management method in a management system comprising one or more stationary battery chargers fixed outside a vehicle; one or more storage battery type vehicles configured to charge a storage battery mounted on a vehicle via a charging cable connecting the vehicle to the one or more stationary battery chargers and be driven using charged power; and a management server configured to manage the one or more stationary battery chargers and the one or more storage battery type vehicles, wherein the one or more storage battery type vehicles and the management server are connected via a network, the method comprising: by the one or more storage battery type vehicles, acquiring state information of the stationary battery charger via the charging cable, and transmitting the state information to the management server; and by the management server, receiving the state information to manage whether or not there an abnormality occurring in the one or more stationary battery chargers.

### Advantageous Effects of Invention

According to the present invention, the storage battery type vehicle configured to charge the storage battery mounted on the vehicle via the charging cable that connects the vehicle to the stationary battery charger fixed outside the vehicle is provided with a state information acquisition unit for acquiring the state information of the stationary battery charger via the charging cable and a communication unit for transmitting out the state information to the management side, which allows for prompt recognition as to whether or not the stationary battery charger is abnormal, without providing the management communication facility such as communication equipment to the stationary battery charger.

### BRIEF DESCRIPTION OF DRAWINGS

FIG. 1 is a schematic diagram illustrating a state where a battery type forklift, which is an example of a storage battery type vehicle that is an embodiment of the present invention, is making a charging by using a stationary battery charger fixed outside the vehicle.

FIG. 2 is a block diagram illustrating an entire configuration of a charge management system and an electrical configuration of the battery type forklift and the stationary battery charger according to the embodiment of the present invention.

FIG. 3 is a flowchart illustrating abnormality notification process steps of the stationary battery charger by the battery type forklift.

FIG. 4 is a flowchart illustrating abnormality notification process steps of the stationary battery charger by a management server.

FIG. 5 is a schematic diagram illustrating a transfer state of abnormality information in the charge management system.

FIG. 6 is a timing chart illustrating timing at which the abnormality information is transmitted to the management server side.

FIG. 7 is a flowchart illustrating notification process steps of the abnormality information and normality information of the stationary battery charger by the battery type forklift.

### DESCRIPTION OF EMBODIMENTS

By referring to the attached drawings, described below will be embodiments for implementing the present invention.

(Charging State of a Battery Type Forklift Using a Stationary Battery Charger)

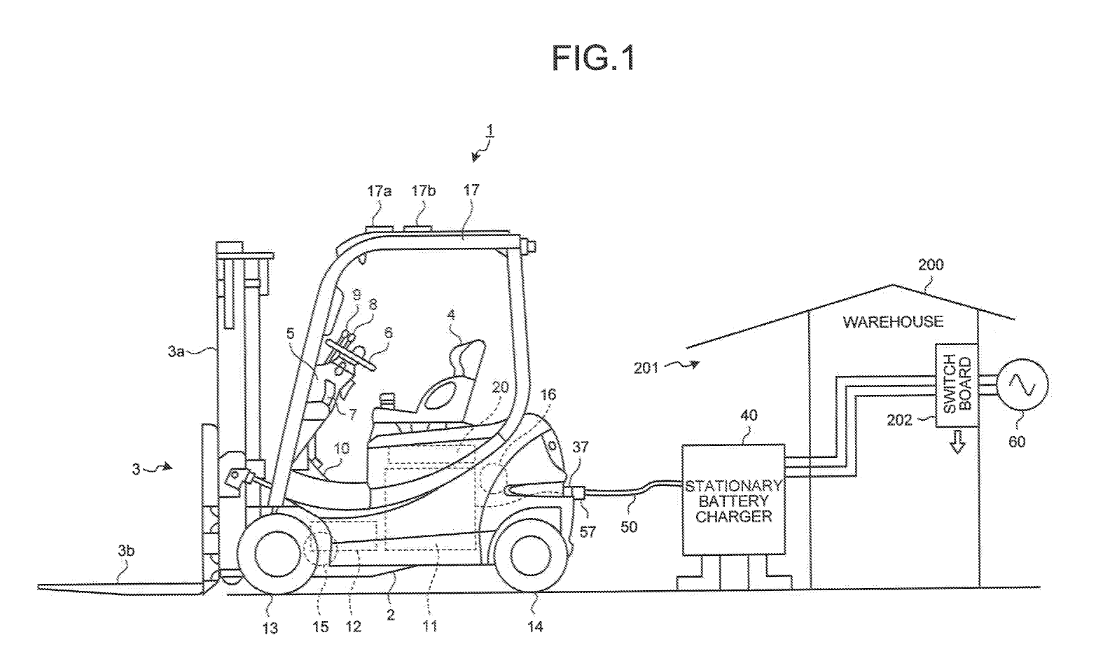

FIG. 1 is a schematic diagram illustrating a state where a battery type forklift, which is an example of a storage battery type vehicle that is an embodiment of the present invention, is making a charging by using a stationary battery charger fixed outside the vehicle. As illustrated in FIG. 1, a stationary battery charger 40 is fixed in an under-eaves area 201 of a warehouse 200, for example. It is noted that the warehouse 200 illustrated in FIG. 1 is an example of the fixing place of the stationary battery charger 40, and the fixing place of the stationary battery charger 40 may be set in a factory where the battery type forklift is operated, a maintenance facility for the inspection and maintenance of the battery type forklift, and the like. The warehouse 200 has a switchboard 202 therein. The switchboard 202 distributes electric power of three-phase 200 V inputted from an external power source 60 and distributes a part of the electric power to the stationary battery charger 40. The stationary battery charger 40 converts the inputted alternating current power of three-phase 200 V into a direct current power of 35 to 108 V. The stationary battery charger 40 is connected with a charging cable 50 that has a charging plug 57 at its end. Under the state where a battery type forklift 1 parked within the reach of the charging plug 57, in response that the charging plug 57 is connected to a charging receptacle 37 of the battery type forklift 1, the charging from the stationary battery charger 40 to a battery 11 of the battery type forklift 1 is started. The charging receptacle 37 is provided to the rear part of the vehicle body of the battery type forklift 1. Further, in response that the charging plug 57 is removed from the charging receptacle 37, the charging is suspended or stopped. This battery type forklift 1 uses the stationary battery charger 40 fixed outside the vehicle without having a battery charger mounted in the vehicle body, so that the vehicle arrangement can be compact and the manufacturing cost can be suppressed. Those who own to plurality of battery type forklifts 1 may buy one battery charger and charge each of the battery type forklifts using that battery charger.

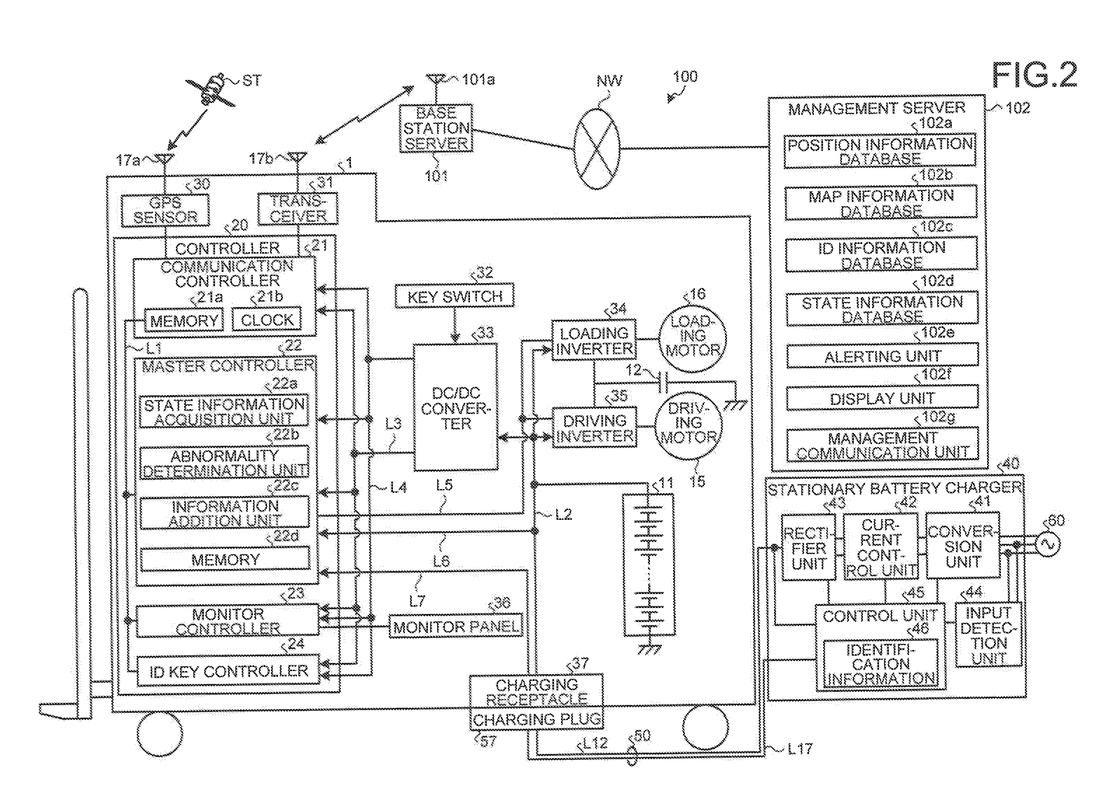

The stationary battery chargers 40 can be arranged in a geographically distributed manner and, at a place of arrangement, a plurality of them may be deployed without limited to one. It is noted that, in this embodiment, the battery type forklift 1 is charged outdoor. Further, as described above, the stationary battery charger 40 is arranged in the under eaves area 201. Therefore, the stationary battery charger 40 including the charging plug 57 and the charging cable 50 is dustproof and waterproof. It is noted that, as illustrated in FIG. 2, the charging cable 50 is configured with a power line L12 for flowing the electric current from the stationary battery charger 40 to the charging plug 57 at the charging and a signal line L17 for transmitting state information including whether or not there is an abnormality from the stationary battery charger 40 to a controller 20.

(Entire Configuration of the Battery Type Forklift)

Described here will be the general feature of the battery type forklift 1. As illustrated in FIG. 1, the battery type forklift 1 has a loading device 3 in the front part of a vehicle body 2. The loading device 3 has a mast 3a and a fork 3b. The fork 3b is guided by the mast 3a to be lifted and lowered. Further, the mast 3a tilts forward and backward to the vehicle body 2.

In the middle of the vehicle body 2, a driver seat 4 is provided. In front of the driver seat 4, provided are a front console 5, a steering wheel 6, a back and forth lever 7, a lift lever 8, and a tilt lever 9. Further, in the anteroinferior part of the driver seat 4, an acceleration pedal 10 is provided. Furthermore, in the anteroinferior part of the driver seat 4, a not-illustrated brake pedal is also provided.

The battery 11 is accommodated under the driver seat 4. The battery 11 that is a storage battery is, for example, an airtight maintenance-free shield battery. It is noted that the battery 11 may be an opened-type open battery. That is, for the battery 11, used can be a rechargeable battery that can be repeatedly charged and discharged such as a lead storage battery, a nickel-metal hydride battery, a lithium ion battery, and so on. The charging receptacle 37 for the charging is connected to the battery 11. It is noted that the battery type forklift 1 illustrated in FIG. 1 has a capacitor 12 mounted in addition to the battery 11 that is the motive power source on the vehicle body 2. While the battery type forklift 1 accumulates the regenerated power of a driving motor 15 to the capacitor 12 to allow for supplementing the motive power source of the battery 11, the battery type forklift 1 may be a battery type forklift 1 whose motive power source is the battery 11 only.

The front part of the vehicle body 2 is provided with driving wheels 13. Also, the rear part of the vehicle body 2 is provided with steering wheels 14. The driving motor 15, which is driven by the electric power accumulated by the charging to the battery 11 and the capacitor 12, is connected to the driving wheels 13 via a not-illustrated motive power transmission mechanism. The driving motor 15 is driven and controlled in response to the operation of the acceleration pedal 10, the back and forth lever 7, and so on and causes the battery type forklift 1 to move forward or move backward. Further, the steering wheels 14 are steered in response to the operation of the steering wheel 6 and able to turn the battery type forklift 1.

The rear part of the vehicle body 2 is provided with a loading motor 16 driven by the electric power of the battery 11 and the capacitor 12. The loading motor 16 is connected to a not-illustrated hydraulic pressure pump. The hydraulic pressure pump hydraulically drives a not-illustrated lift cylinder and tilts the cylinder. The operation of the lift lever 8 causes the lift cylinder to expand and contract and thus the fork 3b is lifted and lowered. The operation of the tilt lever 9 causes the tilt cylinder to expand and contract and thus the mast 3a tilts forward and backward.

It is noted that the upper part of a cabin 17 surrounding the driver seat 4 is provided with a GPS antenna 17a and a transceiver antenna 17b. The upper part of the cabin 17 is called as a head guard. Further, in the lower part of the driver seat 4, a controller 20 for implementing the entire control of the battery type forklift 1 is arranged.

(General Feature of a Charge Management System and Electrical Configuration of the Battery Type Forklift

FIG. 2 is a block diagram illustrating the entire configuration of a charge management system 100 and the electrical configuration of the battery type forklift 1 and the stationary battery charger 40 according to the embodiment of the present invention. As illustrated in FIG. 2, the charge management system 100 is configured with the battery type forklift 1 to which one or more stationary battery chargers 40 to be managed are connected at the charging and with a management server 102. The management server 102 is capable of mutually communicating with the battery type forklift 1. The management server 102 manages the state of the stationary battery charger 40 by using state information of the stationary battery charger 40 transmitted from, the battery type forklift 1. The battery type forklift 1 is able to detect its position based on the electric wave transmitted from a plurality of GPS satellites ST. Further, the battery type forklift 1 is capable of communicating with a base station server 101 by radio communication. Furthermore, the management server 102 is capable of mutually communicating with the base station server 101 via a network NW.

The battery type forklift 1 has a GPS sensor 30 and a transceiver 31. The GPS sensor 30 is a position detection unit and receives the electric wave, transmitted from the GPS satellite ST via a GPS antenna 17a to generate position information indicating the detected position of the battery type forklift 1. It is noted that time data is included in the electric wave transmitted from the GPS satellite ST and the time data is used to generate time information. Further, the transceiver 31 transmits and receives various information such as mobile terminal information, abnormality information, additional information to and from the base station server 101 via the transceiver antenna. 17b and a transceiver antenna 101a of the base station server 101. The details of the mobile terminal information, the abnormality information, the additional information, and so on will be described later.

The battery type forklift 1 has the controller 20, a key switch 32, a. DO/DC converter 33, a loading inverter 34 for driving the loading motor 16, a driving inverter 35 for driving the driving motor 15, a monitor panel 36 arranged on the front console 5, the charging receptacle 37, the battery 11, and the capacitor 12.

The controller 20 has a communication controller 21, a master controller 22, a monitor controller 23, and an ID key controller 24. The communication controller 21, the master controller 22, the monitor controller 23, and the ID key controller 24 are capable of mutually communicating via a communication line L1.

The battery 11 is connected to the loading inverter 34, the driving inverter 35, and the DC/DC converter 33 via a power line L2, and supplies electric power to each device. It is noted that the charging receptacle 37 is connected to the power line L2. The DC/DC converter 33 is connected to the communication controller 21, the master controller 22, the monitor controller 23, and the ID key controller 24 via a power line L3 and supplies each controller with the electric power that has been converted into a predetermined voltage such as 24 V, for example. Further, the key switch 32 is connected to the DC/DC converter 33. When the key switch 32 is in a key-on state, the DC/DC converter 33 sends out a key-on signal of the predetermined voltage to the communication controller 21, the master controller 22, the monitor controller 23, and the ID key controller 24 via a control line L4. The master controller 22 is connected to the loading inverter 34 and the driving inverter 35 via a driving control line L5. The master controller 22 drives and controls the loading inverter 34 and the driving inverter 35 according to the operation amount of the lift lever 8, the tilt lever 9, the steering wheel 6, the back and forth lever 7, and the acceleration pedal 10 to drive the loading motor 16 and the driving motor 15. It is noted that the loading inverter 34 and the driving inverter 35 are connected with the capacitor 12. The capacitor 12 charges the regenerated energy of the driving motor 15 as the electric charge and discharges the accumulated electric charge under the control by the loading inverter 34 and the driving inverter 35. The use of this capacitor 12 allows for significant improvement in the energy usage efficiency of the entire vehicle.

The communication controller 21 obtains the position information from the GPS sensor 30. Also, the communication controller 21 obtains the mobile terminal information and/or the state information of the battery type forklift 1 via the master controller 22 or the monitor controller 23 periodically or in response to the instruction from the management server 102 side. The details of the mobile terminal information and the state information will be described later. The communication controller 21 further includes a clock 21b configuring a time information generation unit. The clock 21b is configured with a time clock IC, for example, and always generates the information indicating time. Further, time data is included in the electric wave transmitted from the GPS satellite ST, and the communication controller 21 receives the time data via the GPS antenna 17a and the GPS sensor 30. The time timed by the time clock IC and the received time data are then compared to correct the current time by a not-illustrated time correction program stored in a memory 21a of the communication controller 21. The time correction program configures the time information generation unit and may be stored in the different storage device from the memory 21a existing within the communication controller 21. The correction of the current time using the time data received from the GPS satellite ST is carried out at a predetermined period set in the time correction program. Hereafter, the corrected current time is referred to as time information. It is noted that the current time obtained by the time clock IC may be used as the time information without correction. That is, either the current time corrected by utilizing the electric wave transmitted from the GPS satellite ST or the current time obtained by such time clock IC may be used for the time information. It is noted that the memory 21a stores various information obtained by the communication controller 21.

The communication controller 21 transmits, to the management server 102 via the transceiver 31, the mobile terminal information including the operation state information obtained by the master controller 22, the position information, the time information, and a vehicle ID obtained by the communication controller 21 itself. This mobile terminal information is immediately transmitted in response to the request from the management server 102 side and periodically transmitted at a preset regular time. Further, the communication controller 21 functions as a communication unit for transmitting, to the management server 102 side, the state information including the occurrence of the abnormality of the stationary battery charger 40. As the additional information, at least one of various pieces of information such as position information of the self vehicle position, time information, identification information 46 of the stationary battery charger 40, operating time of the self vehicle, and charging time of the self vehicle can be added to the above state information. As discussed above, the position information of the self vehicle and the time information of the mobile terminal information among the mobile terminal information is preferably included in the additional information, and at least the position information of the self vehicle and the time information is preferably included in the additional information that is added to the state information. There are a case where this state information is immediately transmitted at the time of occurrence of the abnormality of the stationary battery charger 40 and a case where the mobile terminal information is periodically transmitted at regular time. In the case of the periodical transmission, the state information is transmitted to the management server 102 side together with the mobile terminal information.

The master controller 22 has a state information acquisition unit 22a, an abnormality determination unit 22b, an information addition unit 22c, and a memory 22d. The state information acquisition unit 22a acquires the state information of the stationary battery charger 40 by detecting the charged voltage of the power line L2 at the time of charging via a voltage detection line L6 and further acquiring the charging state of the stationary battery charger 40 from the stationary battery charger 40 side via the signal lines L7 and L17. For the charged voltage of the power line L2 detected via the voltage detection line L6, it is determined whether or not there is an abnormality by the abnormality determination unit 22b. The abnormality determination unit 22b determines whether or not the detected charged voltage within the defined voltage range, for example. As a result of the determination, when the charged voltage is a high voltage or a low voltage that is out of the defined voltage range, the abnormality determination unit 22b determines that there is an abnormality occurring in the stationary battery charger 40 and generates the state information. It is noted that the state information acquisition unit 22a may determine whether or not the detected charged voltage is the voltage that is within the defined voltage range and generate the state information.

Further, the abnormality determination unit 22b determines whether or not the stationary battery charger 40 is abnormal, based on the state information acquired by the state information acquisition unit 22a from the stationary battery charger 40. While the details of the electric configuration of the stationary battery charger 40 will be described later, the state information generated based on the data such as the current and/or the voltage detected by a control unit 45 and the like provided to the stationary battery charger 40 or based on the operation signal and the like is transmitted to the state information acquisition unit 22a of the master controller 22 of the battery type forklift 1 via the signal line L17. The abnormality determination unit 22h then determines whether or not the received state information is information (hereinafter, appropriately referred to as abnormality information) indicating occurrence of the abnormality of the stationary battery charger 40. The abnormality determination unit 22b determines whether or not the state information is the abnormality information according to the data content and/or the type of the received state information. As a result of the determination, if the stationary battery charger 40 is determined to be abnormal, the abnormality determination unit 22b determines that the received state information is the abnormality information. When the stationary battery charger 40 is abnormal, the information addition unit 22c then generates the state information in which the above-described additional information is added to the state information of the stationary battery charger 40. The generated state information of the stationary battery charger 40 is transmitted to the communication controller 21 and then transmitted from the communication controller 21 to the management server 102 side. It is noted that, in the case where the state information is not immediately transmitted, it is stored in the memory 21a. It is noted that, out of the additional information, the position information and the time information may be added at the communication controller 21. Further, the generated state information of the stationary battery charger 40 is transmitted to the monitor controller 23. The monitor controller 23 displays, on the monitor panel 36, that the stationary battery charger 40 is abnormal.

It is noted that the abnormality determination unit 22h may determine whether or not the abnormality is the preset abnormality level based on the state information of the stationary battery charger 40. The master controller 22 may then determine whether or not to make the transmission according to the abnormality level or whether or not to make the immediate transmission. For example, assuming that there are two levels of high and low in the abnormality level and when the abnormality level is high, the state information of the stationary battery charger 40 containing this abnormality level is transmitted to the management server 102 side, while, when the abnormality level is low, the state information of the stationary battery charger 40 is transmitted to the management server 102 side at the preset regular time. For example, the abnormality level is low if the charged voltage of the power line L2 at the time of charging is out of the defined voltage range but within a tolerance voltage range, while the abnormality level is defined to be high if the charged voltage is out of the tolerance voltage range.

The above-described mobile terminal information and/or the state information of the stationary battery charger 40 is stored in the memory 22d. In particular, the memory 22d is a rewritable memory and the information such as updated operation time can be updated.

The monitor controller 23 is connected to the monitor panel 36. The monitor panel 36 is the one including a liquid crystal monitor and predetermined switches, a touch panel, and the like, and is able to input and display various information. It is noted that the monitor panel 36 may be configured with the liquid crystal monitor only and the various information may be inputted by other switches and the like. As described above, when the abnormality of the stationary battery charger 40 is displayed on the monitor panel 36, an alert mark and/or text may be displayed on the liquid crystal monitor, an LED lamp provided to the monitor panel 36 causing the LED lamp to light or flash, or a voice may be uttered by an audio output device such as a speaker. The battery type forklift 1 includes at least one of the monitor panel 36 and/or the LED lamp, an output unit such as the audio output device as described above.

The ID key controller 24 performs the ID management of the operator. For example, in response to a communication request from the management server 102, the operator ID information stored in the ID key controller 24 is transmitted to the management server 102 via the communication controller 21. Further, in response that a key is inserted to the key switch 32 or that the special operation of the monitor panel 36 is made, the ID key controller 24 performs an authentication process of the operator ID in order to determine whether or not the operator is the one who is authorized to drive the battery type forklift 1. As for the key, the ID key in which the electronic chip storing the ID is embedded can be used. Upon authorizing that the operator ID is proper, the ID key controller 24 transmits the signal indicative of the authorization result to the master controller 22. As a result, the master controller 22 outputs the control signal that enables the DO/DC converter 33, the loading inverter 34, and the driving inverter 35 to perform the driving and/or loading operation.

(Electric Configuration of the Stationary Battery Charger)

The stationary battery charger 40 has a conversion unit 41, a current control unit 42, a rectifier unit 43, an input detection unit 44, and the control unit 45. The conversion unit 41 converts the electric power of three-phase 200 V inputted from the external power source 60 into the single-phase alternating current power. The current control unit 42 converts the alternating current power into the direct current power using a switching element such as an IGBT and controls the direct current value. The rectifier unit 43 rectifies the direct current power converted by the current control unit. 42 and converts it into a desired voltage, and supplies the electric power to the battery type forklift 1 side via the power line L12 of the charging cable 50.

The input detection unit 44 detects a voltage value from the two phases of the power lines out of three phases of the power lines inputted from the power source 60 to the conversion unit 41 and detects whether or not the electric power is inputted. The power input state detected by the input detection unit 44 is transmitted to the control unit 45 as a detection signal. The control unit 45 controls each unit within the stationary battery charger 40, in particular, the current control unit 42 to control the quick charging or the normal charging. The control unit 45 detects the direct current outputted from the rectifier unit 43 and detects whether or not the proper electric power is outputted from the stationary battery charger 40 to the battery type forklift 1 side. That is, the control unit 45 generates the state information including the information indicating whether or not there is an abnormality occurring in the stationary battery charger 40 based on the operation of each unit within the stationary battery charger 40 and/or the input and output state of the electric power detected by the input detection unit 44 or the control unit 45, and transmits the state information to the battery type forklift 1 side via the signal line L17 of the charging cable 50. In this case, the identification information 46 that identifies the stationary battery charger 40 held within the control unit 45 may be included in the state information for transmission. It is noted that, for the identification information 46, a serial number given at the manufacturing of the stationary battery charger 40 may be used. The identification information 46 is not limited to the serial number given at the manufacturing as long as the stationary battery charge 40 can be individually identified. Adding the identification information 46 as the additional information facilitates identification of the abnormal stationary battery charger 40 even when multiple stationary battery chargers 40 are arranged at a place inside the warehouse 200, for example.

It is noted that, when there is an inconsistency between the current amount instructed to the current control unit 42 and the current amount outputted from the rectifier unit 43, the state information transmitted by the control unit 45 as described above may be, for example, the state information that is generated assuming that there is an abnormality occurring in the stationary battery charger 40. Further, other state information can be the state information that is generated assuming that there is an abnormality occurring in the stationary battery charger 40 based on the operation of each unit within the stationary battery charger 40. The cause of such state information may be, for example, a short circuit or a defect of the switching element of the current control unit 42, a temperature abnormality of the heat sink within the stationary battery charger 40, a temperature abnormality of a transformer in, the stationary battery charger 40, an actuation of a not-illustrated power source shutdown button, and so on. As discussed above, the state information is generated in the case where the charging voltage is detected as abnormal by the voltage detection line 16 of the battery type forklift 1 and/or the abnormality is detected by the control unit 45 of the stationary battery charger 40.

(Management Server)

The management server 102 has a position information database (DB) 102a, a map information database (DB) 102b, an ID information database (DB) 102c, a state information database (DB) 102d, an alerting unit 102e, a display unit 102f, and a management communication unit 102g.

The position information DB 102a stores the position information of the battery type forklift 1 transmitted from the battery type forklift 1. The map information DB 102b stores map information that is necessary for indicating, on the display unit. 102f, which place each battery type forklift 1 is operated. The ID information DB 102c stores the operator ID information and stores the identification information 46 of the stationary battery charger 40 and the vehicle ID information for individually identifying each battery type forklift 1. The state information DB 102d stores the state information of the stationary battery charger 40. In the case where the state information of the stationary battery charger 40 is the abnormality information indicating that there is an abnormality occurring in the stationary battery charger 40, the alerting unit 102e sets in advance the stepwise alerting levels corresponding to the abnormality levels of the abnormality information and outputs the alert according to the alerting level, for example. The destination of the alert may be the display unit 102f of the management server 102, or a not-illustrated manager terminal connected to the management server 102 or the network NW. Alternatively, it may be configured to allow the service engineer in charge of maintenance and inspection of the battery type forklift 1 or the stationary battery charger 40 to know the alert. The mobile terminal and/or the mobile phone of the service engineer is preset to be able to access the management server 102 via the network NW, and the mobile terminal and/or the mobile phone is preset to be the destination of the alert. Such presetting allows the service engineer to promptly know the abnormality of the stationary battery charger 40.

The management communication unit 102g performs communication process to each battery type forklift 1 via the network NW. In the case where the state information the stationary battery charger 40 is the abnormality information, the management, communication unit 102a transmits the state information of the abnormal stationary battery charger 40 to the battery type forklift 1 other than the battery type forklift 1 which has transmitted the abnormality information. The battery type forklift 1 that has received this state information displays the state information of the abnormal stationary battery charger 40 on the monitor panel 36. In this case, it is preferable that the monitor panel 36 indicates the position of the abnormal stationary battery charger 40 on the map based on the state information and displays an icon representing the abnormality. Further, in may be configured such that the name of the fixing place of each stationary battery charger 40 is associated with the identification information 46 and stored in the ID information DB 102c in advance, the name of the fixing place of the abnormal stationary battery charger 40 is transmitted to each battery type forklift 1 as the state information via the network NW, and the name of the fixing place of the abnormal stationary battery charger 40 is displayed on the monitor panel 36. As discussed above, the information that allows for the identification of the abnormal stationary battery charger 40 is delivered to each battery type forklift 1 and is outputted to the output unit of each battery type forklift 1, so that the operator and the like using each battery type forklift 1 is able to promptly know the stationary battery charger 40 that cannot be used due to the abnormality.

(Abnormality Notification Process of the Stationary Battery Charger by the Battery Type Forklift)

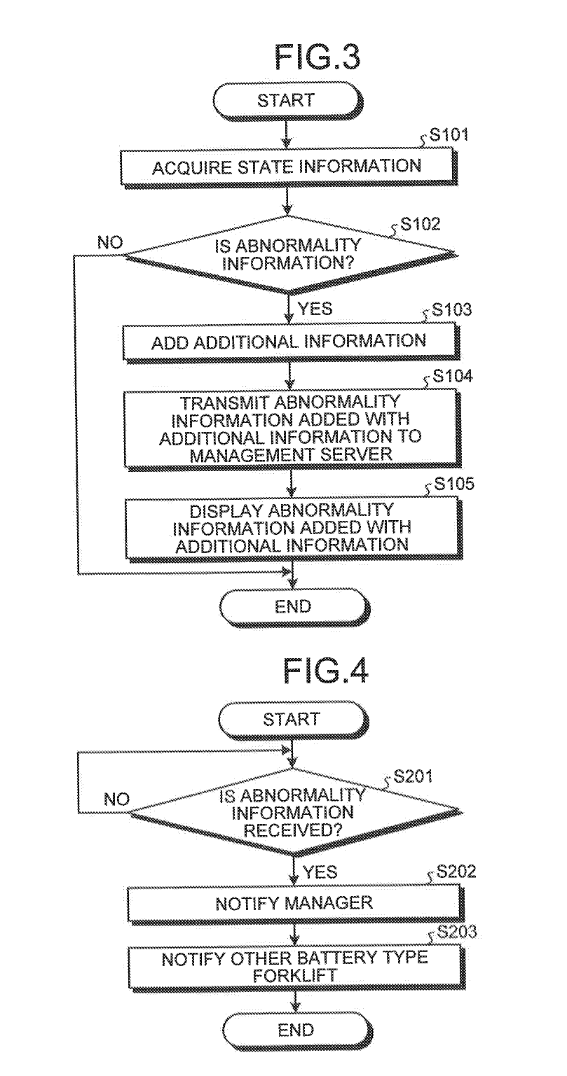

Next, by referring to the flowchart illustrated in FIG. 3, described will be the abnormality notification process steps of the stationary battery charger 40 by the battery type forklift 1. As illustrated in FIG. 3, the state information acquisition unit 22a firstly acquires the state information of the stationary battery charger 40 by the voltage detection of the power line L2 and by the communication process with the control unit 4 of the stationary battery charger 40 via the signal lines L7 and L17 (step S101). Then, based on the state information acquired by the state information acquisition unit 22a, the abnormality determination unit 22b determines whether or not; the state information is the abnormality information indicating that the abnormality currently occurs in the stationary battery charger 40 (step S102). If it is not the abnormality information (step S102, No), the process ends.

On the other hand, if it is the abnormality information (step S102, Yes), the information addition unit. 22c generates the abnormality information added with at least the position information of the battery type forklift 1 under the charging and the time information as described above (step S103). The master controller 22 transmits the abnormality information to, the management server 102 side via the communication controller 21 (step S104). It is noted that, although the information addition unit 22c obtains the position information and the time information from the communication controller 21 and adds it to the abnormality information as the additional information in this example, it may be configured to directly transmit the abnormality information to the communication controller 21 and add the position information and the time information at the communication controller 21 for transmission. It is noted that, since the identification information 46 and/or the operating time can be included in the additional information, the abnormality information is added to the additional information all together at the information addition unit 22c of the master controller 22.

The master controller 22 then transmits, to the monitor controller 23, the abnormality information in which the additional information is added at the information addition unit 22c, displays the abnormality information on the monitor panel 36 (step S105), and the process ends. It is noted that the above-described process is repeated for every predetermined time period.

(Abnormality Notification Management Process of the Stationary Battery Charger by the Management Server)

Next, by referring to the flowchart illustrated in FIG. 4, described will be the abnormality notification management process steps of the stationary battery charger 40 by the management server 102. As illustrated in FIG. 4, the management communication unit. 102g of the management server 102 firstly determines whether or not it has received the abnormality information of the stationary battery charger 40 (step S201). If the management communication unit 102g has not received the abnormality information (step S201, No), this determination process is repeated.

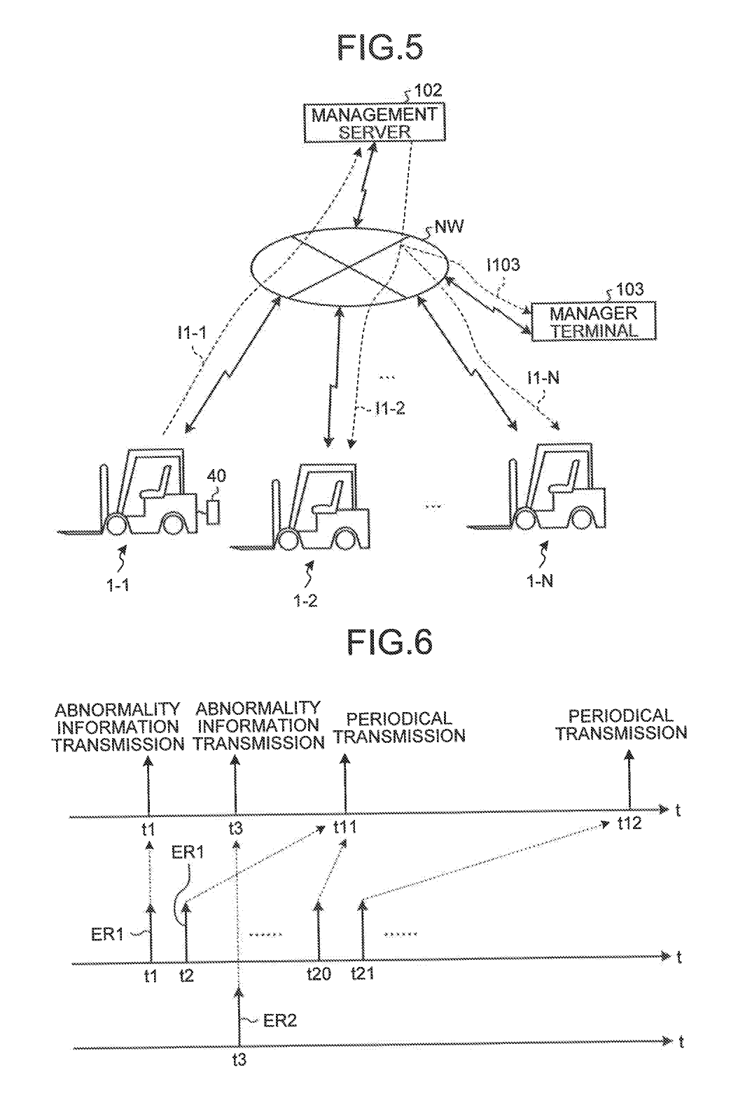

On the other hand, if the management communication unit 102g has received the abnormality information (step S201, Yes), it transmits the abnormality information to a manager terminal 103 via the network NW and notifies the manager or the person in charge of maintenance and inspection of the abnormality information (step S202). Here, FIG. 5 is a schematic diagram illustrating the transfer state of the abnormality information in the charge management system. The broken-line arrows illustrated in FIG. 5 represent the transfer of the abnormality information, and the solid-line arrows represent that the state information including the mobile terminal information and the additional information can be transmitted and received by each of battery type forklifts 1-1 to 1-N, the management server 102, and the manager terminal 103 via the network NW by the radio communication. It is noted that FIG. 5 illustrates the case where some abnormality occurs at the stationary battery charger 40 used by the battery type forklift 1-1, the abnormality information is transmitted from the battery type forklift 1-1 to the management server 102 via the network NW through the transfer path indicated by the broken-line arrow I1-1.

Further, as illustrated in FIG. 5, the management communication unit 102q transmits the abnormality information to battery type forklifts 1-2 to 1-N other than the battery type forklift 1-1 which has transmitted the abnormality information through the transfer paths represented by the arrow I1-2 to I1-N via the network NW, and each of the battery type forklifts 1-2 to 1-N receives the abnormality information via the transceiver antenna 17b and the transceiver 31. The monitor controller 23 of each of the battery type forklifts 1-2 to 1-N displays, on the monitor panel 36, the information that can identify the stationary battery charger 40 at which the abnormality currently occurs (step S203), and completes the process. This step S203 allows other battery type forklifts 1-2 to 1-N to share the information of the abnormal stationary battery charger 40. That is, each operator and the like using the battery type forklift 1 is able to promptly know the unusable stationary battery charger 40 due to the abnormality, which can suppress unnecessary operation of moving the battery type forklift 1 to the place where the unusable stationary battery charger 40 is arranged, without knowing that it is unusable one, for example.

It is noted that, it is preferable that, upon receiving the abnormality information, the management server 102 displays the icon indicating the detail of the abnormality represented by the abnormality information on the display unit 102f based on the position information indicated by the abnormality information and also displays the time of the occurrence of the abnormality. This allows the state of each stationary battery charger 40 to be managed all together. In addition, when multiple stationary battery chargers 40 are arranged in a position within the warehouse 200, for example, the stationary battery charger 40 can be identified based on the identification information 46 of each stationary battery charger 40. Further, upon receiving the abnormality information, the management server 102 transmits the abnormality information via the transfer path represented by the arrow I103 to the manager terminal 103 of the manager who manages the stationary battery charger 40 at which the abnormality occurs. The abnormality information may be transmitted to the mobile phone or the mobile terminal of the service engineer as described above along with the manager terminal 103 or in place of the manager terminal 103.

(Immediate Transmission and Periodical Transmission of the Abnormality Information)

FIG. 6 is a timing chart illustrating the timing at which the abnormality information is transmitted to the management server 102 side. As illustrated in FIG. 6, when an abnormality ER1 occurs in the stationary battery charger 40 at the time t1, the communication controller 21 immediately transmits the abnormality information to the management server 102 side at the time t1, because the time t1 is not the time t11 of the periodical transmission of the mobile terminal information. At the time t1, it may be configured to obtain the time information by the above-described time information generation unit as the additional information and transmit the time information to the management server 102 side. Because the master controller 22 is repeating the abnormality detection for every predetermined time period, it again detects the abnormality ER1 of the stationary battery charger 40 at the time t2 after a predetermined time period from the time t1. However, because the abnormality ER1 from the time t2 to t20 is the second or subsequent and the same as the abnormality ER1, this abnormality information of the abnormality ER1 is transmitted including the mobile terminal information at the time t11 of the subsequent periodical transmission in order to reduce the communication cost. Also at the time t11, the time information of the above-described time information generation unit may be obtained as the additional information and transmitted to the management server 102 side. It is noted that, when the same abnormality ER1 occurs at the time t21 between the time t11 of the subsequent periodical transmission and the time t12 of the further subsequent transmission, this abnormality information is transmitted along with the mobile terminal information at the time t12 of the subsequent periodical transmission. It is noted that, in the case where the abnormality determination unit 22b determines whether or not it is the predetermined set abnormality level based on the state information of the stationary battery charger 40 as described above, the abnormality information may be transmitted to the management server 102 side as described below. For example, when the abnormality level is high, the state information is immediately transmitted to the management server 102 side, while, when the abnormality level is low, the state information is periodically transmitted to the management server 102 side. Alternatively, regardless of whether the abnormality level is high or low, the state information may be immediately transmitted to the management server 102 side.

On the other hand, the timing of the immediate transmission or the periodical transmission may be the time when the battery type forklift 1 is being charged by the stationary battery charger 40, or the time when the battery type forklift 1 is being operated for some operation and the like. It is preferable that the abnormality information is transmitted to the management server 102 side, if possible, when the abnormality occurs in the stationary battery charger 40 during the charging at night, for example. However, in the case where the abnormality information cannot be transmitted due to the poor communication environment at the time of the immediate transmission, the abnormality information to be transmitted is once stored in the memory 21a of the communication controller 21 and, in the next day for example, that abnormality information may be transmitted to the management server 102 side when the battery type forklift 1 is operated. Even if the communication environment of the place where the stationary battery charger 40 is arranged is poor, moving the battery type forklift 1 allows for the transmission of the abnormality information to the management server 102 side in the place of good communication environment, which ensures the manager and the like to recognize the abnormality of the stationary battery charger 40.

On the other hand, when an abnormality ER2 different from the abnormality SRI occurs at the time t3 before the time t11 of the periodical transmission, the abnormality information of the abnormality ER2 is immediately transmitted at the time t3. Also at the time t3, the time information by the above-described time information generation unit may be obtained as the additional information and transmitted to the management server 102 side.

(Transmission Process of the Normality Information)

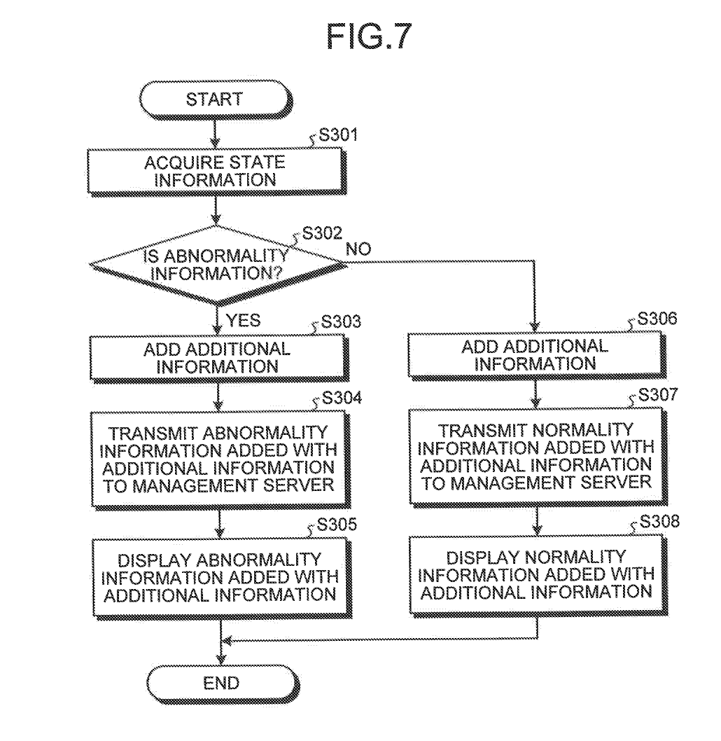

In the process illustrated in FIG. 3, the state information in which the abnormality information includes only the case where the abnormality occurs in the stationary battery charger 40 is transmitted to the management server 102 side and further the state information is displayed on the monitor panel 36 of the battery type forklift 1 which has transmitted that state information to the management server 102 side. In contrast, in the process illustrated in FIG. 7, when the stationary battery charger 40 is normal, the state information of the normality information is transmitted to the management server 102 side and displayed on the monitor panel 36 of the battery type forklift 1 which has actually transmitted this state information.

That is, the abnormality determination unit 22b determines that the state information is not the abnormality information indicating the abnormality of the stationary battery charger 40 (step 3302, No) based on the state information acquired by the state information acquisition unit 22a (step 3301), the information addition unit 22c generates the normality information that is added with the position information and the time information of the battery type forklift 1 which is under the charging (step S306). Here, the position information and the time information may not be added to the normality information. This is because there is a case where it is enough for the manager to recognize that the stationary battery charger 40 is normal. The master controller 22 transmits the normality information to the management server 102 side via the communication controller 21 (step S307). As set forth, the process illustrated in FIG. 3 causes the abnormality information or the normality information to be always transmitted to the management server 102 side, which allows for the prompt recognition of the abnormality of the stationary battery charger 40 and, also, the recognition as to whether or not the stationary battery charger 40 has returned from the abnormal state to the normal state.

The master controller 22 then transmits, to the monitor controller 23, the normality information to which the additional information is added by the information addition unit 22c, displays the normal state on the monitor panel 36 (step 3308), and the process ends. It is noted that displaying the normality state on the monitor panel 36 can be realized by various forms such as the display on the liquid crystal monitor, the flashing of the LED, the voice, and the like as described in the case of the display of the above-described abnormality state.

It is noted that other processes of steps S301 to 3305 are the same as the processes of steps S101 to S105. Further, the management server 102 that has received the normality information may transmit the normality information to each battery type forklift 1. Further, each battery type forklift 1 that has received the normality information via the transceiver antenna 17b and the transceiver 31 may display, on the monitor panel 36, the information that the stationary battery charger 40 is able to be used.

As described above, in this embodiment, when the abnormality occurs in the stationary battery charger 40, the additional information such as the position information and the time information of the self vehicle that is managed by the battery type forklift 1 connected to the stationary battery charger 40 at the time of charging can be transmitted to the management server 102 side along with the state information indicating the abnormality of the stationary battery charger 40 using the communication function and the communication equipment of the battery type forklift 1. Therefore, it is not necessary to provide the communication equipment to the stationary battery charger 40, or it is not necessary to provide the management communication facility such as communication equipment to the fixing place of the stationary battery charger 40. If communication equipment were provided to the stationary battery charger 40, the task of examining the fixing place would be necessary taking into consideration of the communication environment by the radio communication. However, according to the battery type forklift 1 or the charge management system and the charging management method of the embodiment as described above, such operation can be reduced. Further, according to the battery type forklift 1 or the charge management system and the charging management method of the embodiment, the manager is able to promptly recognize the abnormality when the abnormality occurs in the stationary battery charger 40.

By the way, when the abnormal stationary battery charger 40 has been repaired, the person in charge of maintenance and inspection such as the manager or the service engineer may transmit, from the manager terminal 103 to the management server 102, the restoration information indicating that is has been repaired, for example. Further, the manager and the like may set the mobile phone and/or the mobile terminal in place of the manager terminal 103 to be able to access the management server 102 and transmit the restoration information from the mobile phone and/or the mobile terminal to the management server 102. The management server 102 that received the restoration information transmits the restoration information to each battery type forklift 1. The battery type forklift 1 that has received the restoration information displays, on the monitor panel 36, the information indicating that the abnormal stationary battery charger 40 has been repaired.

Further, although the normality information is transmitted to the management server 102 side in the process illustrated in FIG. 7, the management server 102 may manage it by assuming that the state where no abnormality information is transmitted is the state where the normality information is transmitted.

Furthermore, it may be configured such that the abnormality determination unit 22b is not provided and the state information obtained is directly transmitted to the management server 102 side regardless of the content, of the state information being the abnormal or the normal.

Further, although the normality information is transmitted to the management server 102 side in the process illustrated in FIG. 7, the management server 102 manages it by assuming that the abnormal stationary battery charger 40 has been repaired if the normality information has been received after the abnormality information has been received. Then, the management server 102 may transmit, to the other battery type forklift 1, the information indicating that the abnormal stationary battery charger 40 has been repaired and display it on the monitor panel 36.

Furthermore, although the communication controller 21 and the master controller 22 are the separate controllers in the above-described embodiment, the communication controller may be inherent within the master controller 22.

Further, although the above-described embodiment is the system in which the state information of the stationary battery charger 40 is supposed to be transmitted from the battery type forklift 1 to the management server 102 side, it is not limited to the above and may be the system having the area in which the direct communications can be made among respective battery type forklifts 1 and the manager terminal 103 without using the management server 102.

Furthermore, although the above-described embodiment has been provided assuming that the capacitor 12 is used in addition, to the battery 11, it may be applied to the one that is driven by the battery 11 only without using the capacitor 12. Further, the battery type forklift 1 is an example of the industrial vehicles as described above, and the present embodiment can be applied to general industrial vehicles. For example, it can be applied to the electronic construction machines configured to charge electric power to a battery from an external power source without an engine mounted, drive an electric motor by the electric power accumulated in the battery as a motive power source, drive a hydraulic pump by the electric motor to supply hydraulic oil to a hydraulic cylinder of an operation machine, and operate the operation machine.

### REFERENCE SIGNS LIST

1 BATTERY TYPE FORKLIFT
2 VEHICLE BODY
3 LOADING DEVICE
3a MAST
3b FORK
4 DRIVER SEAT
5 FRONT CONSOLE
6 STEERING WHEEL
7 BACK AND FORTH LEVER
8 LIFT LEVER
9 TILT LEVER
10 ACCELERATION PEDAL
11 BATTERY
12 CAPACITOR
13 DRIVING WHEEL
14 STEERING WHEEL
15 DRIVING MOTOR
16 LOADING MOTOR
17 CABIN
17a GPS ANTENNA
17b TRANSCEIVER ANTENNA.
20 CONTROLLER
21 COMMUNICATION CONTROLLER
21a MEMORY
21b CLOCK
22 MASTER CONTROLLER
22a STATE INFORMATION ACQUISITION UNIT
22b ABNORMALITY DETERMINATION UNIT
22c INFORMATION ADDITION UNIT
22d MEMORY
23 MONITOR CONTROLLER
24 ID KEY CONTROLLER
30 GPS SENSOR
31 TRANSCEIVER
32 KEY SWITCH
33 CONVERTER
34 LOADING INVERTER
35 DRIVING INVERTER
36 MONITOR PANEL
37 CHARGING RECEPTACLE
40 STATIONARY BATTERY CHARGER
41 CONVERSION UNIT
42 CURRENT CONTROL UNIT
43 RECTIFIER UNIT
44 INPUT DETECTION UNIT
45 CONTROL UNIT
46 IDENTIFICATION INFORMATION
50 CHARGING CABLE
57 CHARGING PLUG
60 POWER SOURCE
100 CHARGE MANAGEMENT SYSTEM
101 BASE STATION SERVER
101a TRANSCEIVER ANTENNA
102 MANAGEMENT SERVER
102a POSITION INFORMATION DATABASE
102b MAP INFORMATION DATABASE
102c ID INFORMATION DATABASE
102d STATE INFORMATION DATABASE
102e ALERTING UNIT
102f DISPLAY UNIT
102g MANAGEMENT COMMUNICATION UNIT
103 MANAGER TERMINAL
200 WAREHOUSE
201 UNDER-EAVES AREA
202 SWITCH BOARD
L1 COMMUNICATION LINE
L2, L3, L12 POWER LINE
L4 CONTROL LINE
L5 DRIVING CONTROL LINE
L6 VOLTAGE DETECTION LINE
L7, L17 SIGNAL LINE
NW NETWORK
ST GPS SATELLITE

1. A storage battery type vehicle configured to charge a storage battery mounted on a vehicle via a charging cable connecting the vehicle to a stationary battery charger fixed outside the vehicle, the storage battery type vehicle comprising:
a state information acquisition unit configured to acquire state information of the stationary battery charger via the charging cable; and
a communication unit configured to transmit the state information to outside immediately or periodically in accordance with a situation,
wherein when the state information acquisition unit acquires abnormality information indicating an abnormality of the stationary battery charger for a first time, the communication unit transmits the abnormality information to the outside immediately, and when the state information acquisition unit acquires the abnormality information from a second time, the communication unit transmits the abnormality information to the outside periodically.

2. A storage battery type vehicle
configured to charge a storage battery mounted on a vehicle via a charging cable connecting the vehicle to a stationary battery charger fixed outside the vehicle, the storage battery type vehicle comprising:
a state information acquisition unit configured to acquire state information of the stationary battery charger via the charging cable; and
a communication unit configured to transmit the state information to outside immediately or periodically in accordance with a situation,
wherein when an abnormality level of abnormality information indicating an abnormality of the stationary battery charger acquired by the state information acquisition unit is high, the communication unit transmits the abnormality information to the outside immediately, and when the abnormality level of the abnormality information acquired by the state information acquisition unit is low, the communication unit transmits the abnormality information to the outside periodically.

3. A storage battery type vehicle configured to charge a storage battery mounted on a vehicle via a charging cable connecting the vehicle to a stationary battery charger fixed outside the vehicle, the storage battery type vehicle comprising:
a state information acquisition unit configured to acquire state information of the stationary battery charger via the charging cable; and
a communication unit configured to transmit the state information to outside immediately or periodically in accordance with a situation,
wherein when the state information acquisition unit acquires abnormality information indicating an abnormality of the stationary battery charger during a charging of the storage battery, the communication unit transmits the abnormality information to the outside immediately, and when the abnormality information which is immediately transmitted cannot be transmitted, the communication unit temporarily stores the abnormality information, and subsequently, when the storage battery type vehicle is operated, the communication unit transmits the abnormality information, which is temporarily stored, again.

4. The storage battery type vehicle according to claim 1 further comprising an information addition unit configured to add additional information to the state information.

5. The storage battery type vehicle according to claim 4, wherein the additional information is position information of the vehicle.

6. The storage battery type vehicle according to claim 4, wherein the additional information is time information of time of occurrence of abnormality of the stationary battery charger.

7. The storage battery type vehicle according to claim 1, wherein the state information includes identification information of the stationary battery charger.

8. The storage battery type vehicle according to claim 4, wherein the additional information is operating time and/or charging time of the vehicle.

9. (canceled)

10. (canceled)

11. A charge management system comprising a management server configured to manage one or more the stationary battery chargers and one or more the storage battery type vehicles according to claim 1,
wherein the outside is the management server, and
wherein the one or more storage battery type vehicles and the management server are connected via a network,
wherein the one or more storage battery type vehicles comprises an output unit configured to output the state information,
wherein the management server comprises a management communication unit,
wherein the management communication unit of the management server notifies the state information to the one or more storage battery type vehicles that are other than the storage battery type vehicle that has transmitted the state information and are connected to the network, and
wherein the storage battery type vehicle that has received the state information from the management server outputs the received information to the output unit.

12. The charge management system according to claim 11, wherein the state information is abnormality information of the stationary battery charger and is information to which one of more pieces of information of position information of the storage battery type vehicle that has acquired the state information, time information of time of occurrence of abnormality of the stationary battery charger, operating time of the storage battery type vehicle, charging time of the storage battery type vehicle, and identification information of the stationary battery charger are added.

13. The charge management system according to claim 11,
wherein, upon receiving state information indicating restoration of the stationary battery charger, the management server notifies the one or more storage batter type vehicles of the state information indicating the restoration, and
wherein the storage battery type vehicle that has received the state information indicating the restoration from the management server outputs the received state information indicating the restoration to the output unit.

14. A charge management method
comprising a management server configured to manage the one or more stationary battery chargers and one or more the storage battery type vehicles according to claim 1,
wherein the outside is the management server, and
wherein the one or more storage battery type vehicles and the management server are connected via a network,
wherein the one or more storage battery type vehicles output the state information to the one or more stationary battery chargers and the one or more storage battery type vehicles,
wherein the management server notifies the state information to the one or more storage battery type vehicles that are other than the storage battery type vehicle that has transmitted the state information and are connected to the network, and
wherein the storage battery type vehicle that has received the state information from the management server outputs the received information to inside of the storage battery type vehicle.
